(19) United States
(12) Patent Application Publication
(10) Pub. No.: US 2018/0139865 A1
(43) Pub. Date: May 17, 2018

(54) Microstructure water cooling unit for cooling of an electrical or electronic component that already includes a flow diverter and a flow distributor

(71) Applicants: Nathanael Draht, Schloss Holte (DE); Andreas Rudnicki, Braunschweig (DE)

(72) Inventors: Nathanael Draht, Schloss Holte (DE); Andreas Rudnicki, Braunschweig (DE)

(21) Appl. No.: 15/353,802

(22) Filed: Nov. 17, 2016

(51) Int. Cl. H05K 7/20

(52) U.S. Cl. CPC H05K 7/20254; H05K 7/20281; H05K 7/20263; H05K 7/20272

(57) ABSTRACT

Microstructure water cooling unit for cooling of an electrical or electronic component that already includes a flow diverter and a flow distributor which change the water flow from the inlet to the water chamber and create a harmonized water output in the injection plate which improves the cooling capability of the whole water cooling unit.

Microstructure water cooling unit for cooling of an electrical or electronic component that already includes a flow diverter and a flow distributor.

### FIELD OF THE INVENTION

This invention relates to a cooler for electrical or electronic components, in detail to fluid coolers for PC components like processors, graphics chips, memory units, voltage converters, hard drives and other electrical or electronic components, that dissipate heat, that are known for example from the patent DE102008058032.5 US6, 105.373 U.S. Pat. No. 8,240,362B2 U.S. Pat. No. 8,245,746B2 and DE102004018144B4. Furthermore there is known a cooler with an injection plate from US2009/0071625A1.

### DESCRIPTION OF THE RELATED ART OF TECHNIQUE

From DE102004018144B4 it is known, for example, that in modern computers, the electronic components of graphics cards and processors, the so-called CPUs, are inherently subject to high thermal loads which occur during their operation. Due to the ever-narrowing circuit structures and the increasing performance of these processors they heavily heat up during operation. To ensure a high and uniform computer power and to protect the processor from thermal damage, all of these were actively cooled. A conventional cooling air provides a cooler in form of a front fan that supplies the electronic device regulated or unregulated with cooling air. The heated air is discharged to the environment in general.

In high-performance computers this type of cooling has limitations. Particularly in large computer systems is the heating of the rooms where computers are set up a problem which is encountered with the use of air conditioners with high energy costs.

As an alternative to pure air cooling liquid cooler for electronic processors are available amplified, which comprise a bottom plate, usually made of copper, on which one on side the processor is arranged, while the other side is subjected to a stream of cooling water. This cooling water is, for example, provided through an injection plate with feed and discharge connections, with which the bottom plate is in contact.

Reference may be made here by way of example of coolers, which are known from U.S. Pat. No. 6,105,373, U.S. Pat. No. 5,239,443. Thus, the one described in U.S. Pat. No. 6,105,373 thermoelectric cooler has a bottom plate and a multi-piece nozzle plate, wherein at the first side of the bottom plate an electronic component that needs to be cooled can be mounted and opposite the injection plate can be attached. On the injection plate, a feed port and a discharge port for a liquid cooling medium are included. For the distribution of the cooling medium there is a chamber formed in the injection plate, which is connected to the feed port and to the outlet holes or ejection nozzles. The outlet openings of the ejection nozzles or discharge orifices are directed towards the electronic component facing away from the side of the bottom plate, so that it is actively cooled by the cooling medium. The discharge of the heated cooling medium from the cooling space is formed between the outside of the chamber and the electronic component facing away from the side of the base plate.

Although this liquid-cooled cooling device has significant advantages relative to air-cooled cooling devices for an electronic component, it can, as regards the cooling effect, be further improved. It should be referred to the microstructure cooler DE102008058032.5, which preferably allows a further increase due to the new etching technology through the production of very fine structures. The base plates that are manufactured from etching process require very thin (for example 1 mm) materials, so that they can be screwed only with expensive thread insert with the top. Therefore, current microstructure cooler again are manufactured by milling and possibly additionally provided with a top and an injection plate. The bottom of an so produced cooler is between 3 and 5 mm thick and usually must be processed very complicated to achieve inside a remaining thickness of preferably <0.5 mm and a fin height of 2 to 3 mm.

Microstructure coolers of the current state of the art are challenged to allow a sufficiently high flow and the greatest possible cooling capacity. To allow a large flow rate, the cooling channels must have a certain height in the soil, for example, 4 mm, and a corresponding width, for example 1 mm, so that the microstructure cooler is not a flow brake for the water circuit. In order to achieve the greatest possible cooling power, the cooling channels may be as thin as possible, for example <0.5 mm, and the height as low as possible, such as <2 mm, so that the coolant can absorb the heat directly from the heat transferor point. However, so designed coolers have a very high flow resistance, so that thus constructed cooler with conventional pumps used in computer water cooling systems cannot be carried out effectively. The currently in such coolers used technique requires the water inlet to the middle of the bottom plate through an injection plate, and may even have water recirculation technology to increase the flow rate and the cooling performance. Although the pre-chamber is made as big as possible, the fluid does not spread to all cooling channels evenly but preferably flows into the middle cooling channels while the cooling channels located on the two outer sides are scarcely supplied with the cooling fluid. Additionally, a non-uniform lateral pressure distribution in the top (for example, from the left) results in a lateral water supply in the pre-chamber so that the cooling channels on the opposite (right) side of the water cooler are preferably flowed through. As a result, the heat transfer capacity drops in the upper, lower and left regions which have a poor flow rate opposite the high flow center-right-lying areas. This means a non-optimum utilization of the cooling capacity potential of the water cooler. Even with a central water inlet directly above the pre-chamber, the problem arises as the supply hose must normally be bent by 90° within a few centimeters because the space is limited in the usual computer cases or machine housings and servers. This bent supply hose results in the same effect as the side inlet: The fluid stream is deflected to one side, thereby creating the unsymmetrical flow of the fluid with the known disadvantages of the reduced cooling capacity.

Against this background, the invention is based on the object of solving the problem that despite a large pre-chamber the fluid flow is unevenly distributed and additionally deflected to one side due to a water inlet on a side or a bend tube or a 90° fitting when using central water supply and thereby increasing the overall cooling performance without impairing the flow rate or significantly increasing the production costs.

This object is achieved by the features of the main claim, while advantageous embodiments and refinements of the invention can be derived from the sub-claims.

The invention is based on the discovery that the water flow in the bottom of a micro-structure cooler cannot be improved since any flow optimization in the form of an increase or enlargement of the cooling channels leads to an expense of cooling capacity. Furthermore, current models have the problem that the fluid flow is distributed unevenly over the cooling channels and therefore the full, theoretically possible cooling capacity cannot be called up. Therefore, an additional component (so-called flow divertor) was applied to the top of the middle plate and an additional component (so-called flow distributor) was added in the injection pre-chamber, which deflect the fluid stream so as to allow an even pressure distribution in the width (through the flow divertor) and an even pressure distribution of the fluid flow over the entire length of the injection slot (through the flow distributor).

The increase in performance is based on an even distribution of the fluid flow to all cooling channels by adding a flow distributor and a flow divertor. It is known that the higher the water flow, the higher the possible heat transfer. This curve, however, is not linear (double flow=double cooling capacity), but logarithmic, so that a further increase in the currently high flow rates still offers only minimal advantages (with unchanged water cooler design). On the other hand, a halving of the flow leads to a significant loss in the heat transfer. If a water cooler now has a strong flow in the middle cooling channels (the side opposite to the inlet), this results in a minimal local increase in the heat transfer at this location, compared with a water cooler which is uniformly flowed through, and the poorly flowed external and opposing cooling channels suffer a significant loss of heat transfer. In sum, a cooler with uneven flow has a significantly lower heat transfer and thus a significantly lower cooling capacity.

Lots of current models are already equipped with an injection plate and a slot-shaped or perforated injection opening. However, these injection openings fail in the task of uniformly distributing the fluid flow to all cooling channels. It is possible to retrofit these existing microstructure coolers by retrofitting a flow distributor into the existing pre-chamber so that the cooling performance of existing models is increased by the even distribution of the fluid flow. Unlike the installation of the flow distributor as an additional component, it is also possible to integrate it directly into parts of the middle plate or the cover. The possibility of retrofitting a flow diverter is difficult, since the feed channel in the top must be changed.

When developing new models, it is possible to manufacture the flow diverter with the necessary changes in the top and the flow distributor very cost-effectively as an injection molded part made of plastic and to insert it on the middle plate or into the injection pre-chamber so that existing tools for the upper and lower part of the middle plate can be still used. However, it would also be possible, in the case of new developments, to produce the bottom area of the middle plate and the flow distributor in one piece, or to integrate the flow diverter and/or the flow distributor into the upper part of the middle plate in order to reduce production costs and tooling costs.

As a further advantage, it is now also possible to use larger bottom plates with more cooling channels. Up to now, hardly a performance increase could be determined by a broadening of the cooling channel area. In the current state of the art, the additional cooling channels which are added to the outer areas are only flowed through with so little cooling fluid that a performance increase of the entire cooler is hardly detectable. With a flow distributor, on the other hand, the fluid flow can also be distributed uniformly to larger widths, so that an increase in the overall cooling capacity can be achieved without great technical complexity.

The lower part of the middle plate is sealed against the upper part of the middle plate by an O-ring in order to avoid a parallel fluid flow past the cooling channels. However, the seal may also be carried out by an adhesive or other suitable sealant.

Depending on the application and system conditions such as the parallel operation of several coolers (for example for multi-processor systems) or the cooling of other components such as graphics chips, hard drives, memory chips and other heat dissipating components, the water cooler as well as the flow diverter and the flow distributor can be individually adapted.

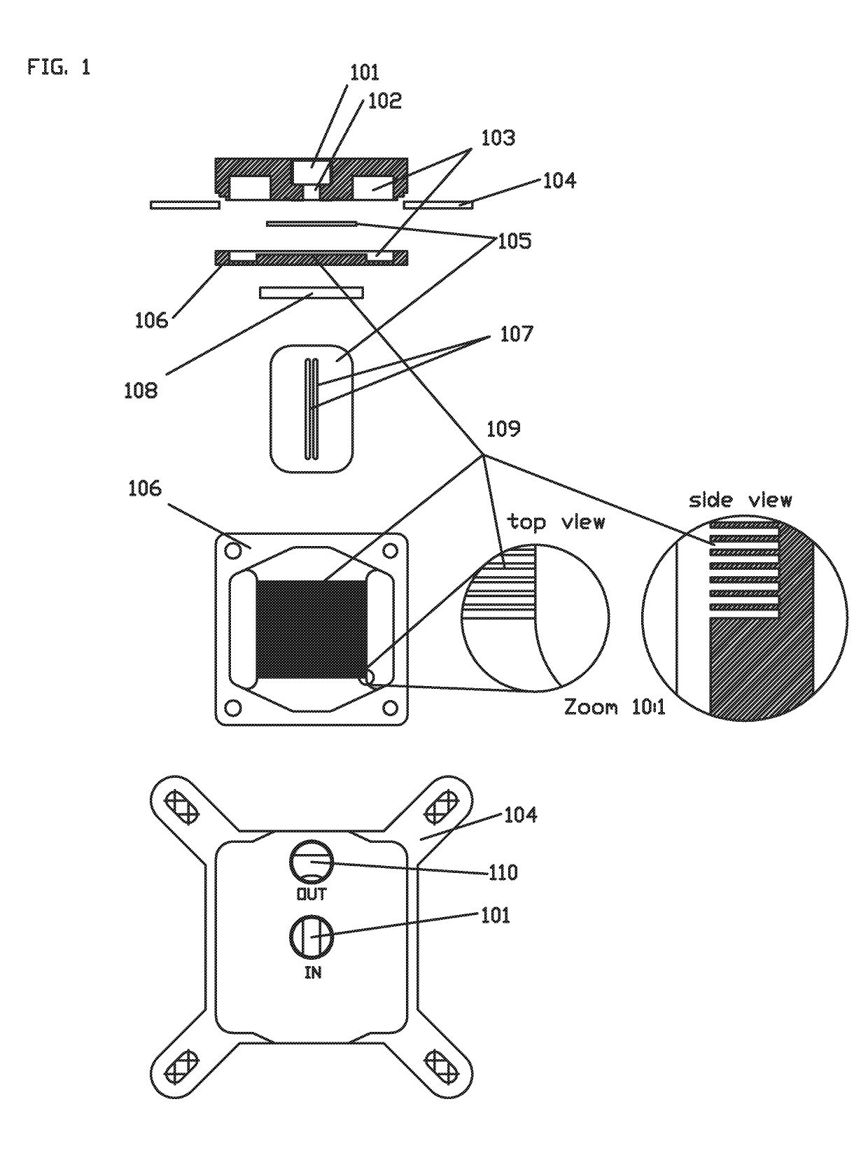

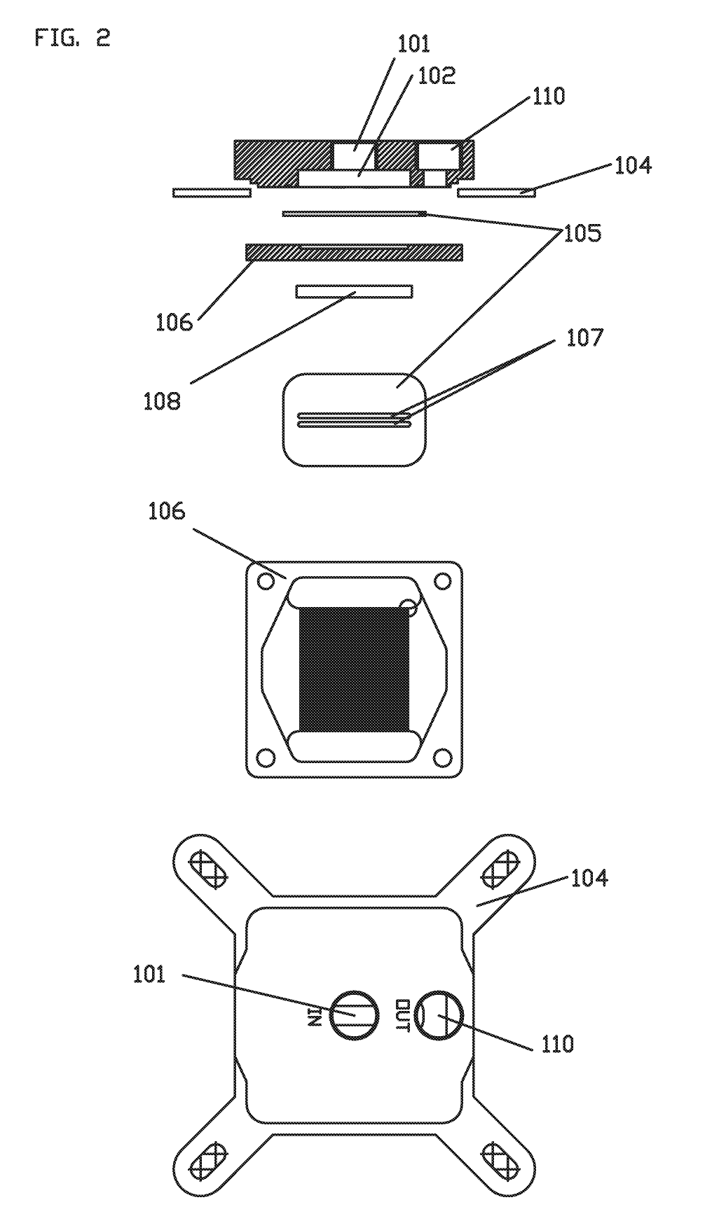

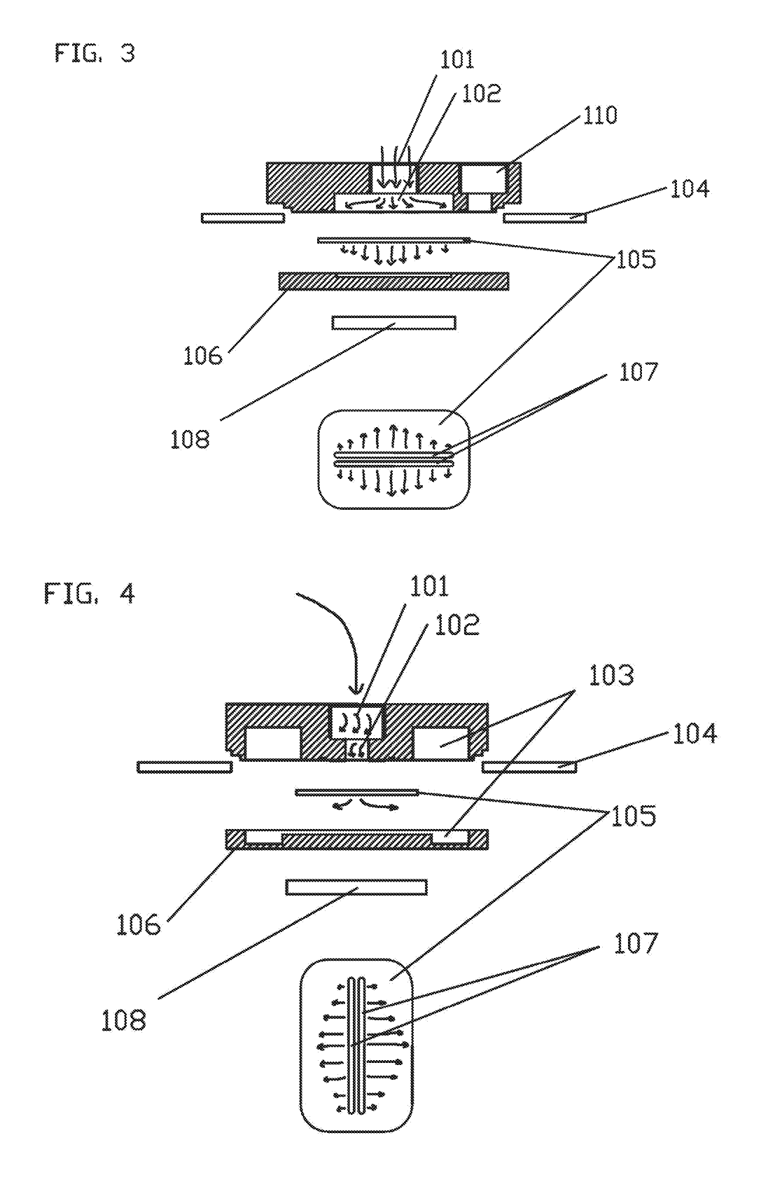

FIG. 1, FIG. 2, FIG. 3 and FIG. 4 show the typical current CPU cooler. It consists of inlet (101), pre-chamber (102), backwater chamber (103), mounting plate (104), injection plate (105), base plate (106), slits (107), a fin structure/cooling channels (109), and the outlet (110) . Additionally the heat source (108) is shown.

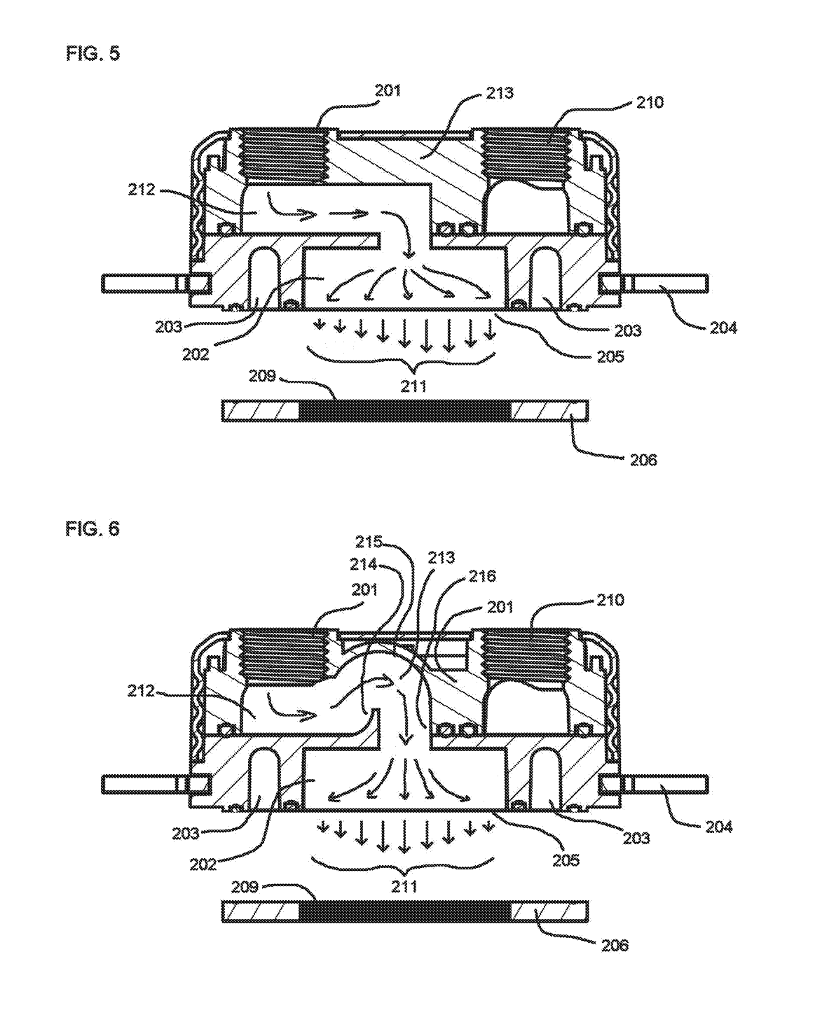

FIG. 5 shows the typical current CPU cooler. It consists of inlet (201), pre-chamber (202), backwater channel (203), mounting plate (204), injection plate (205), base plate (206), fin structure/cooling channels (209), the outlet (210), the feed channel (212) and the top (213). Additionally the heat source (208) and a graphic of the pressure distribution (211) are shown.

FIG. 6—Innovative water cooler with flow diverter. It consists of inlet (201), pre-chamber (202), backwater channel (203), mounting plate (204), injection plate (205), base plate (206), fin structure/cooling channels (209), the outlet (210), the feed channel (212), the top (213), ramp (214), curvature (215) and a straight outlet shaft (216). Additionally the heat source (208) and a graphic of the pressure distribution (211) are shown.

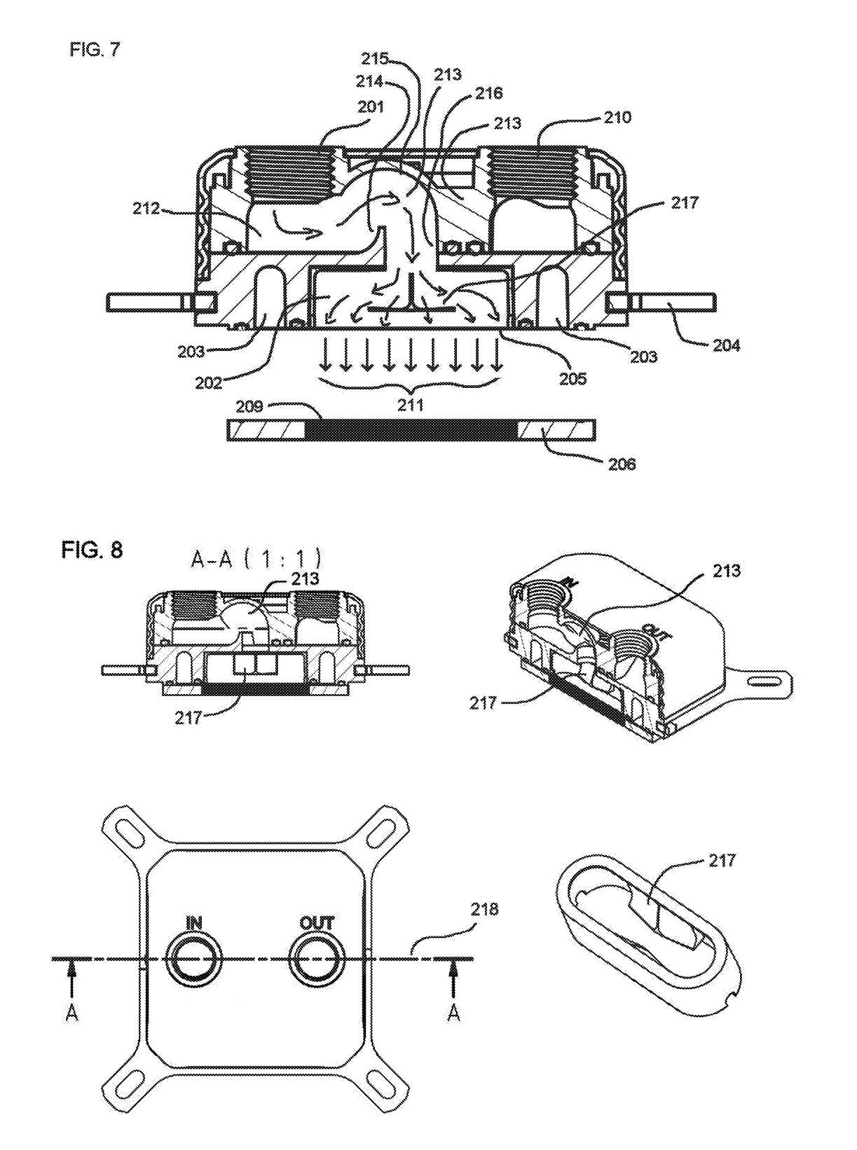

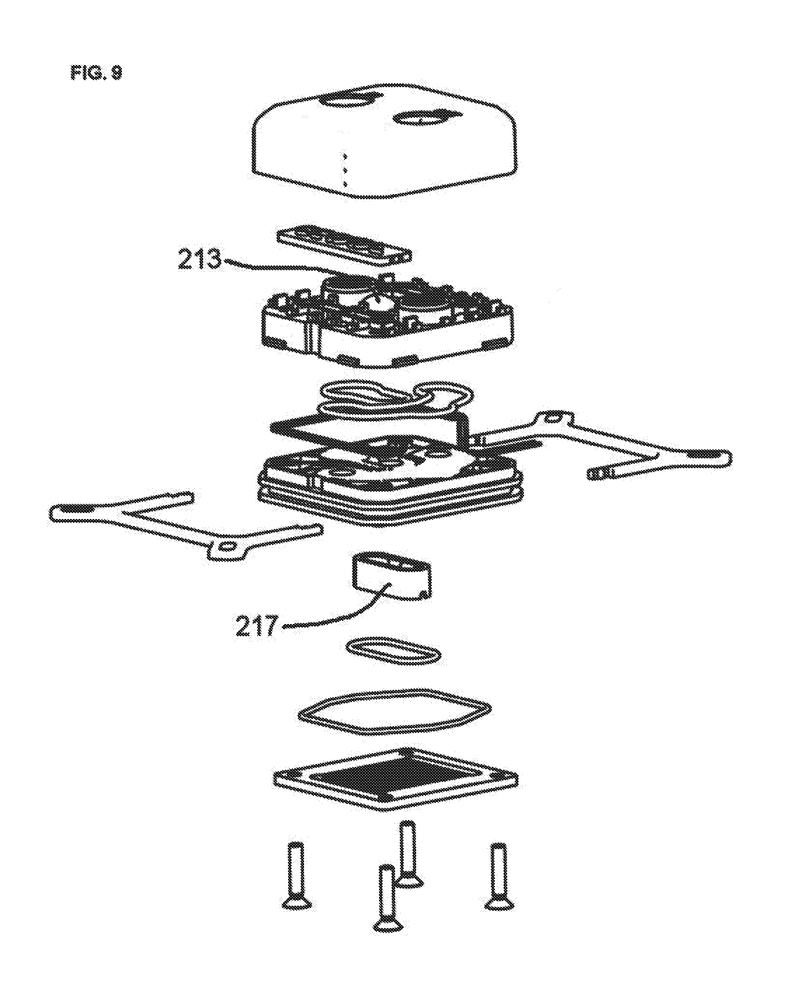

FIG. 7, FIG. 8 and FIG. 9—Innovative water cooler with flow diverter and flow distributor. It consists of the same components as FIG. 6 but has also a flow distributor (217) already included.

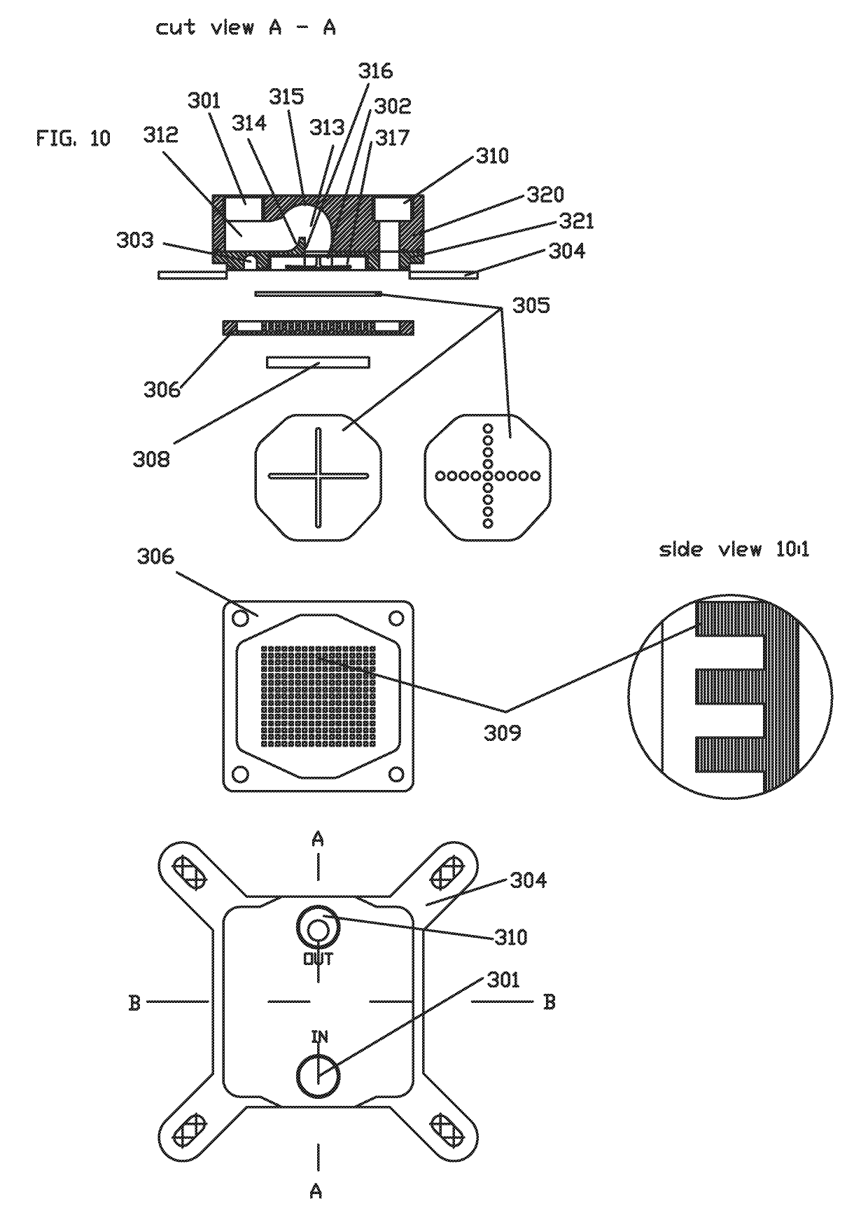

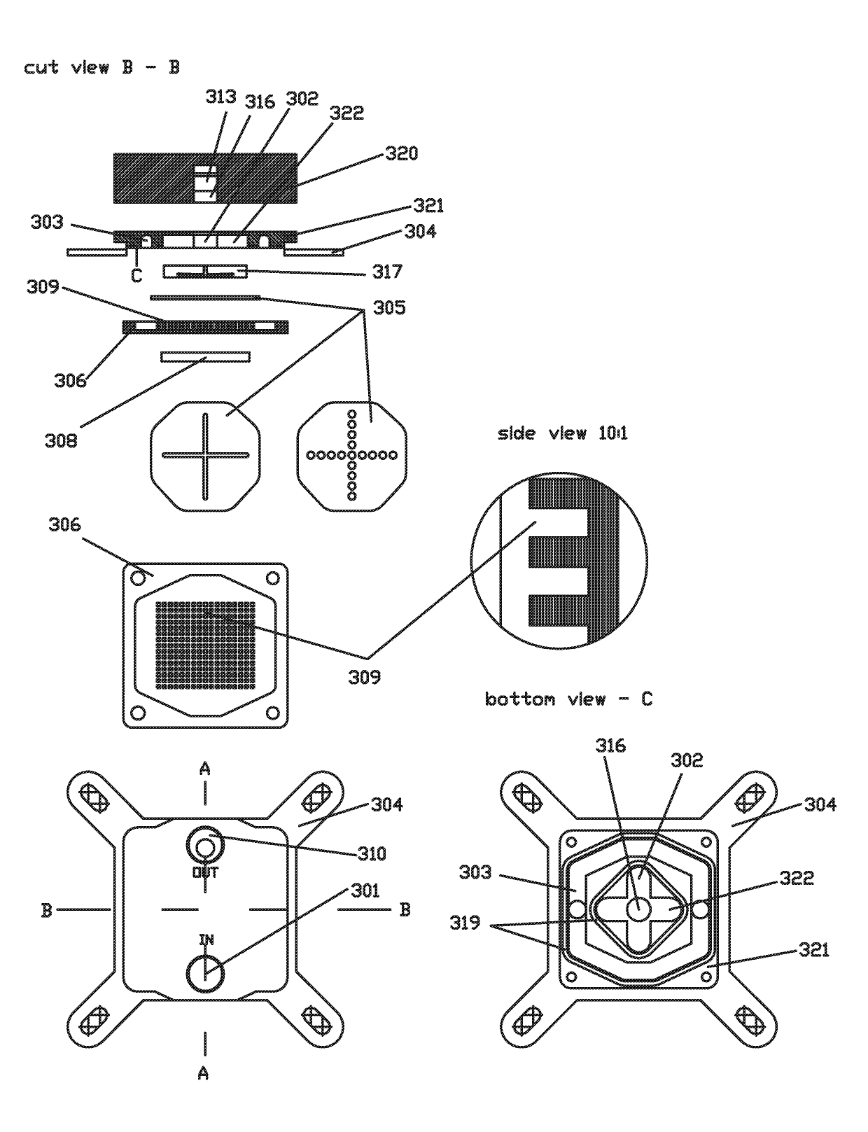

FIG. 10 —Innovative water cooler with flow diverter and flow distributor in cross arrangement. It consists of inlet (301), pre-chamber (302), backwater channel (303), mounting plate (304), injection plate (305), base plate (306), fin structure/cooling channels (309), the outlet (310), the feed channel (312), the top (313), ramp (314), curvature (315), straight outlet shaft (316), flow distributor (217), sealing (319), top (320), middle plate (321) and the 90° rotated pre-chamber extension (322). Additionally the heat source (308) is shown.

### SUMMARY

The invention concerns a microstructure water cooling unit for cooling of an electrical or electronic component that already includes a flow diverter and a flow distributor.
which consists of a bottom plate, an injection plate, a middle plate and a top
which has a flow diverter included in the top or at the top of the middle plate
which has a flow distributor included in the pre-chamber
which provides an overall symmetric water pressure in the injection slit
which allows a flow increase
which improves the heat transfer from the base plate to the cooling medium
which improves the existing coolers in the cooling capacity and the flow rate
which enables a wider channel area (means additional channels) in the base plate at constant or increased cooling power and flow rate for new coolers with which a fluid operated cooler for electrical or electronic components can be improved in terms of the cooling capacity and the flow rate by installing a flow diverter and a flow distributor which provides an overall symmetric water pressure in the injection slit.

### EMBODIMENT

An exemplary embodiment is described with reference to the accompanying figures. In the drawings:

FIG. 1 (view perpendicular) and FIG. 2 (view horizontally)—Prior art. The CPU cooler pictured here shows the typical current CPU cooler art. The cooling medium is distributed through an inlet (101) into a prechamber (102), and from there through the injection plate (105) concentrically with one or two slits (107) of the fin structure/cooling channels (109) directed to the base plate (106) to escape from there through the cooling channels (109) outwardly and thereby absorb the heat from the heat source (108). The cooling medium is then collected in the backwater chamber (103) and discharged via outlet (110). The whole water block is mounted via the mounting plate (104).

FIG. 3 and FIG. 4—Prior art. The CPU cooler shown here shows the fluid flow or the pressure distribution in a water cooler according to typical prior art. The cooling fluid flows in through the inlet (101) and is distributed in the pre-chamber (102). Due to a suboptimal pressure distribution in the pre-chamber, a different pressure and thus fluid flow results at the injection plate (105). The pressure or fluid flow is here marked with arrows of different length, the longer, the greater. In the case of FIG. 3, we have drawn the best possible solution according to the current state of the art. Here, a pressure distribution or fluid flow is seen at the slots, which is the largest in the center while the outer regions are only slightly traversed. FIG. 4 shows the further altered pressure distribution or fluid flow due to the bent inlet hose which frequently occurs in practice. The cooling fluid already has a non-rectilinear flow pattern in the inlet (102), which continues in the prechamber (105) and goes into the injection plate (105) and leads in addition to the already disadvantageous distribution (see FIG. 3) in the side opposite to the inlet bend (the right side in the drawing) to a real adverserly pressure distribution . Thus, a horizontal (rightward) orientation is obtained from the known vertical distribution. The result is shown schematically in the arrows.

FIG. 5—Prior art. The CPU cooler shown here shows the fluid flow or the pressure distribution in a water cooler according to typical prior art. In the cooler, the inlet (201) is not located in the center but in the side of the top (213). There is a feed channel (212) which leads to the pre-chamber (202). Due to the lateral flow direction thus produced, a lateral pressure or fluid flow also results in the injection plate (205), which leads to the pressure distribution (211) or fluid flow outlined here. This results in uneven flow velocities in the microstructure (209) in the bottom (206). The cooling fluid is collected in the backwater channel (203) and discharged through the outlet (210). The water cooler is attached via the mounting plate (204).

FIG. 6—Innovative water cooler with flow diverter. The CPU water cooler shown here has a lateral inlet (201) in the top (213) from where the cooling fluid is deflected into the feed channel (212) in order to get further into the flow diverter (213). The flow diverter (213) consists of a ramp (214) and an opposing curvature (215), as well as a straight outlet shaft (216), which in total result achieves that the cooling fluid reaches the pre-chamber (202) without a lateral twist. This leads to a pressure distribution or fluid flow, as shown here (211), which now has its peak in the middle and decreases towards the sides. Although an uneven pressure distribution or fluid flow is still present here, this distribution is advantageous to that shown in FIG. 5. The problem of the lateral inlet (201) is hereby remedied.

FIG. 7, FIG. 8 and FIG. 9—Innovative water cooler with flow diverter and flow distributor. In addition to the design and characteristics shown in FIG. 6, the cooling medium, after the outlet shaft (216), impacts the flow distributor (217) which distributes the cooling fluid from the center uniformly outwards into the whole pre-chamber (202), so as to form a symmetrical, uniform pressure distribution or flow of fluid as outlined (211). This allows a fluid flow uniformly distributed over the entire surface of the microstructure (209) to improve the heat absorption of the bottom plate (206). The drawing FIG. 8 shows two sectional views (left 2d, right 3d) showing the flow diverter (213) and flow distributor (217) in the water cooler, as well as the associated cutting edge (218) in the view from above. The flow distributor (217) is also shown here as a single component. In FIG. 9, the water cooler is shown as an exploded drawing.

FIG. 10—Innovative water cooler with flow diverter and flow distributor in cross arrangement. The CPU water cooler shown here has a lateral inlet (301) in the top (320) from where the cooling fluid is deflected into the feed channel (312) in order to get further into the flow diverter (313). The flow diverter (313) consists of a ramp (314) and an opposing arch (315) and a straight outlet shaft (316) which opens into the pre-chamber (302). The drawing shows the view from above and the cross-sectional view of a water cooler with a flow distributor (317) in a cross-arrangement, in which the cooling fluid after leaving the outlet shaft (316) instead of only in 2 directions (as in FIGS. 6 to 9) is distributed into 4 Directions in the pre-chamber (302 and 322) evenly. In this application, the injection plate (305) then has a cross-shaped arrangement, either with injection slots or with injection holes in various geometric designs, the fluid then impinging on the pin structure (309) of the bottom plate (306), and then via the return channel (303) to the outlet (310). In addition, the mounting plate (304) and the heat source (306) are shown as well as the sealing (319), the standard pre-chamber (302) and the pre-chamber 90° rotated extension (322).

1. Microstructure water cooling unit for cooling of an electrical or electronic component that already includes a flow diverter and a flow distributor
With a bottom plate, an injection plate, a middle plate and a top,
In which at the top of the middle plate a flow diverter is included
In which at the bottom of the middle plate a flow distributor is included
In which the bottom plate has parallel cooling fins
In which the injection plate has a slotlike opening
In which the flow diverter is built like a ramp, so that the feed channel is narrowed and the incoming fluid is distracted
In which the flow distributor is bevelled and narrows the pre-chamber so that the incoming fluid is distracted to the sides
In which the combination of flow diverter and flow distributor spread evenly the fluid into the whole pre-chamber
In which the injection slit is placed centrally over the middle of the heat emitting part of the bottom plate
So that a steady fluid injection pressure occurs over the whole injection slit, which leads to a harmonized fluid flow in the microstructure channels of the bottom plate which increases the cooling performance of the microstructure water cooling unit.

2. Microstructure water cooling unit as described in claim 1, characterized in that the middle plate (consisting of top part, flow distributor and injection plate) is not build of multiple parts but for easier mass production some parts are combined to one part together and/or implemented into the top

3. Microstructure water cooling unit as described in claim 1, characterized in that the flow distributor is equipped by an additional 90° twisted axis, so that the fluid is spread evenly not only in a slot-like pre-chamber but in a cross-like pre-chamber, so that through cross-like injections slits or holes the fluid is evenly injected onto a channel or cross-channel microstructure in the bottom plate.
